(19) United States
(12) Patent Application Publication
(10) Pub. No.: US 2008/0169510 A1
(43) Pub. Date: Jul. 17, 2008

(54) PERFORMANCE ENHANCEMENT ON BOTH NMOSFET AND PMOSFET USING SELF-ALIGNED DUAL STRESSED FILMS

(75) Inventors: Mahender Kumar, Fishkill, NY (US); Huilong Zhu, Poughkeepsie, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: International Business Machines Corporation, Armonk, NY (US)

(21) Appl. No.: 11/623,871

(22) Filed: Jan. 17, 2007

(51) Int. Cl. H01L 29/78; H01L 21/336

(52) U.S. Cl. 257/368; 438/275; 257/E21.409; 257/E29.255

(57) ABSTRACT

In an integrated circuit comprising both PMOSFETs and NMOSFETs, carrier mobility is enhanced on both types of FETs using dual stressed films. The adverse impact of having both layers of stressed films along the boundary between different types of films is eliminated by utilizing self-alignment of the edges of a second stressed film to a preexisting edge of a first stressed film. At the boundary between the two stressed films, one stressed film abuts another but no stressed film overlies another stressed film. By avoiding any overlap of stressed films, the stress exerted on the MOSFET channels is maximized.

### FIELD OF THE INVENTION

The present invention generally relates to semiconductor devices for integrated circuits, and particularly to CMOS transistors with improved performance through strain engineering.

### BACKGROUND OF THE INVENTION

Manipulating stress is an effective way of improving the minority carrier mobility in a metal oxide semiconductor filed effect transistor (MOSFET) and increasing the transconductance (or reduced serial resistance) of the MOSFET that requires relatively small modifications to semiconductor processing while providing significant enhancement to MOSFET performance.

When stress is applied to the channel of a semiconductor transistor, the mobility of carriers, and as a consequence, the transconductance and the on-current of the transistor are altered from their original values for an unstressed semiconductor. This is because the applied stress and the resulting strain on the semiconductor structure within the channel affects the band gap structure (i.e., breaks the degeneracy of the band structure) and changes the effective mass of carriers. The effect of the stress depends on the crystallographic orientation of the plane of the channel, the direction of the channel within the crystallographic orientation, and the direction of the applied stress.

The effect of uniaxial stress, i.e., a stress applied along one crystallographic orientation, on the performance of semiconductor devices, especially on the performance of a MOSFET (or a “FET” in short) devices built on a silicon substrate, has been extensively studied in the semiconductor industry. For a PMOSFET (or a “PFET” in short) utilizing a silicon channel, the mobility of minority carriers in the channel (which are holes in this case) increases under uniaxial compressive stress along the direction of the channel, i.e., the direction of the movement of holes or the direction connecting the drain to the source. Conversely, for an NMOSFET (or an “NFET” in short) devices utilizing a silicon channel, the mobility of minority carriers in the channel (which are electrons in this case) increases under uniaxial tensile stress along the direction of the channel, i.e., the direction of the movement of electrons or the direction connecting the drain to the source. These opposite requirements for the type of stress for enhancing carrier mobility between the PMOSFETs and NMOSFETs have led to prior art methods for applying at least two different types of stress to the semiconductor devices on the same integrated chip.

Different methods of “stress engineering,” or “strain engineering” as it is alternatively called, on the channel of a MOSFET have been known in the prior art.

One group of methods create a “global stress,” that is, a stress applied to a general transistor device region generated from the substrate. A global stress is generated by such structures as SiGe stress relaxed buffer layers, Si:C stress relaxed buffer layers, or silicon germanium structures on an insulator.

Another group of methods generate a “local stress,” that is, a stress applied only to local areas adjacent to the channel from a local structure. A local stress is generated by such structures as stress liners, embedded SiGe source/drain structures, embedded Si:C source/drain structures, stress-generating shallow trench isolation structures, and stress-generating silicides. An increase in the on-current of up to 50% and an overall chip speed increase up to 40% have been reported on semiconductor devices utilizing these methods.

One of the most common methods of applying a local stress is the use of stressed liners, or “stressed films”. Since each stressed liner has a certain stress level, either compressive or tensile, two separate stressed liners, commonly called “dual liners,” are used to separately create a tensile stress and a compressive stress in two different regions of the same integrated circuit. An exemplary method for forming two separate liners is disclosed in the U.S. patent application Publication No. 2005/0093030 A1 to Doris et al., which discloses the use of two separate liners such that an NFET area is covered with a tensile film that directly overlies underlying NFETs, an optional dielectric layer, and a compressive film while a PFET area is covered only with the compressive film. The film stack over the NFET area applies tensile stress to the underlying NFETs and the compressive film over the PFET area applies compressive stress to the underlying PFETs so that both PFETs and NFETs have enhanced performance through stress engineering.

The presence of a compressive film over portions of a PFET area near the boundaries between the PFET area and an NFET area according to the prior art is not advantageous, however, since the compressive film applies a compressive stress to the underlying PFETs through the tensile film and the optional dielectric layer. The tensile stress that the tensile film generates is therefore partially negated by the compressive stress that the overlying compressive film generates under the boundary region in which both the compressive film and the tensile film overlap.

Removal of the compressive film from above the NFET area faces some challenges since an additional mask is needed to etch away the compressive film from over the NFET area. Alignment of the edge of an exposed pattern on a photoresist to the edge of the preexisting patterned tensile film is subject to inherent lithographic overlay variations. Depending on the overlay of the photoresist to the edge of the preexisting patterned tensile film, a region without any tensile film or compressive film may be formed or alternatively, a region with both the tensile film and the compressive film may be formed. The nature of the boundary between these two films affects the level of stress on the adjacent MOSFETs and causes variations in the performance of the MOSFETs. Furthermore, the nature of the boundary also affects a subsequent etch process of contact holes in source and drain regions and on the top of gate electrodes, e.g., on a gate electrode of an inverter.

The performance of the MOSFETs thus depends on the overlay of the etched compressive film to the tensile film. Even if the topography of the compressive film and the tensile film is reversed, the problem still remains since a partial removal of a stressed blanket film from a structure that contains a patterned film with a different level of stress underneath is prone to generation of different topographies at the boundary of each film depending on the overlay of the edges of the two stressed films. Moreover, large overlap between the tensile and compressive nitride films makes the formation of contact holes more difficult since the etch process needs to remove both stressed films from the contact area. However, the underlap between the tensile and compressive nitride films causes over etched silicided in the underlap area, which causes damage of the silicided area. Therefore, it is desirable to self-align the tensile and compressive nitride films.

Referring to FIG. 1, an exemplary dual stressed film structure according to the prior art is shown. A first MOSFET 99 and a second MOSFET 199 are shown with a substrate 10, a shallow trench isolation (STI) 20, and a boundary region 72 which contains a vertical stack of a first stressed film 50 and a second stressed film 70. The first MOSFET 99 comprises a portion of the substrate 10, a gate dielectric 30, a gate conductor 38 which comprises a gate polysilicon 32 and a gate silicide 36, a spacer 34, source and drain regions 40, a source and drain silicide 42, a first stressed film 50, and an etch stop layer 52. Similarly, the second MOSFET 199 comprises another portion of the substrate 10, a gate dielectric 30, a gate conductor 38 which comprises a gate polysilicon 32 and a gate silicide 36, a spacer 34, source and drain regions 40, a source and drain silicide 42, and a second stressed film 70.

The first stressed film 50 applies a first stress to the first MOSFET 99 and the second stressed film 70 applies a second stress to the second MOSFET 199. The first stress and the second stress are different, and very often, the two stresses are opposite in nature, i.e., one is compressive and the other is tensile. Most often, the substrate is a silicon substrate and a compressive stress is applied to a p-type MOSFET (PMOSFET) and a tensile stress is applied to an n-type MOSFET (NMOSFET). The first MOSFET 99 may be a PMOSFET with a compressive stress or an NMOSFET with a tensile stress depending on the method of fabrication. A MOSFET or opposite polarity with opposite kind of stress is selected for the second MOSFET 199 relative to the first MOSFET 99.

In general, one stressed film has only one level of stress irrespective of the location of the film. To exert two different levels of stress on two different devices, formation of two different types of stressed films is required. In the prior art, attempts to produce stressed films with significant stress levels of opposite polarity (i.e., one compressive film and one tensile film) have met with limited success. For example, using ion implantation to relax a portion of a stressed film has so far produced films with a limited magnitude of stress. Fabrication of structures with a high level of stress of both types, for example, a compressive stress greater than about 150 MPa and a tensile stress greater than about 150 MPa, thus requires two separate depositions of two different stressed films.

One of the common aspects of the prior art methods that utilize two separate stressed films, or “dual stressed films,” is the inability to self-align the edge of the second stressed film 70 to the edge of the first stressed film 50. The use of two lithographic patterning is inevitable if only the film that applies the right kind of stress is to remain over each MOSFET in a CMOS circuit that employs both mobility enhanced PMOSFETs and mobility enhanced NMOSFETs. One stressed film is deposited and patterned first, which is designated as a “first stressed film” 50 in FIG. 1. The edge of the first stressed film 50 is defined after a lithographic patterning and etching of the first stressed film 50. Thereafter, the second stressed film 70 is deposited, lithographically aligned to the existing edge of the first stressed film 50, patterned, and etched.

However, any lithographic alignment has inherent non-zero overlay variations for an alignment to exiting alignment marks. Even some of the currently most advanced lithographic tools such as an 193 nm DUV lithography systems have a total overlay tolerance, or overlay variations, between about 40 nm to about 50 nm, which is comparable to the thickness of the stressed films, which is typically from about 50 nm to about 100 nm. Trying to align the edge of the second stressed film to the edge of the first stressed film may result in about 50 nm or more of overlap between the two films or alternatively, may result in a gap of about 50 nm or more wherein no stressed film exists. Since the two films have opposite stress types, such variations in the overlay would result in excessive variations in the stress applied to the devices near the boundary between the two types of stressed films. To reduce the variations in the stress applied to the nearby devices, a structure such as shown in FIG. 1 is typically employed in the prior art to insure that the second stressed film 70 overlies the first stressed film 50 even in the worst case of overlay variations. However, since the two films have opposite stress types, vertically overlaying the two stressed films result in partial cancellation of the stress applied to the nearby devices. The stacked local structure 72 in FIG. 1 that includes a stack of a portion of the first stressed film 50 and a portion of the second stressed film 70 effectively neutralizes or diminishes the stress near the boundaries wherein the two types of stressed films adjoin.

While novel methods may be employed to alleviate this problem, for example, as disclosed by Yang et al. in the U.S. patent application Publication 2006/0099793 A1, in which a current conducting member is utilized with an underlapped pair of a tensile film and a compressive film to maintain a consistent level of stress in each MOSFET region, introduction of any additional structure tends to add to the chip area and hence, becomes a less economical option. Furthermore, application of a maximum level of stress on the MOSFETs near a boundary would be possible only if the two stressed films do not have an overlap or an underlap, i.e., do not form an area wherein two types of stresses cancel or diminish each other.

Therefore, there exists a need for a method of reducing or eliminating the deleterious effects of overlay variations on the topography of dual patterned stressed films.

Also, there exists a need for a structure wherein the deleterious effects of overlay variations on the topography of the dual patterned stressed films are minimized or eliminated.

Furthermore, there exists a need for a structure with a boundary region wherein a first stressed film and a second stressed film adjoin and the boundary region delivers consistent level of stress to the adjacent MOSFET devices irrespective of the overlay of the photoresist used to pattern a second stressed film.

### SUMMARY OF THE INVENTION

The present invention addresses the needs described above by providing structures and methods in which dual stressed films are self-aligned at their edges to avoid the deleterious effects of overlay variations.

The present invention also provides structures and methods in which the boundary region between two stressed films delivers a consistent level of stress irrespective of the overlay of the photoresist used in patterning the second stressed film.

According to the present invention, a semiconductor structure with self-aligned dual stress liners is disclosed, which comprises:

a substrate;

a first metal-on-semiconductor field effect transistor (MOSFET) with a first channel formed on the substrate;

a second MOSFET with a second channel formed on the substrate;

a first film formed over the first MOSFET and providing a first stress at least to the channel of the first transistor; and

a second film located over the second MOSFET and providing a second stress at least to the channel of the second transistor, wherein the second film has an angled ledge that is self-aligned to an edge of the first film and the first stress is not equal to the second stress.

Preferably, the first film abuts the second film at the boundary. Therefore, a side surface of the first film contacts a side surface of the second film. However, the first film does not overlie the second film and the second film does not overlie the first film. Therefore, an area wherein both the first film and the second film are stacked vertically does not exist according to the present invention. This contrasts with prior art structures with dual stressed films which contain an area wherein a stack of both stressed films, with or without an optional intervening dielectric layer between them, exists along the boundary of the two films with different stress levels.

Preferably, both the first film and the second film are dielectric films. Examples of dielectric films include silicon nitride, silicon oxynitride, and silicon oxide of various doping. Preferably, the first stress and the second stress are of the opposite types. For example, the first stress is a tensile stress and the second stress is a compressive stress. More preferably, the first stress is a tensile stress greater than 150 MPa in magnitude and the second stress is a compressive stress greater than 150 MPa in magnitude. Most preferably, the first stress is a tensile stress greater than 500 MPa in magnitude and the second stress is a compressive stress greater than 500 MPa in magnitude. In a highly preferred embodiment, the first MOSFET to which the first stress is applied is an n-type MOSFET (NMOSFET) and the second MOSFET to which the second stress is applied is a p-type MOSFET (PMOSFET).

Preferably, the first film directly contacts a gate conductor of the first MOSFET, which may include a gate silicide on the gate conductor, and source and drain regions of the first MOSFET, which may include a silicide formed on the source and drain. The first film abuts the second film preferably on a shallow trench isolation (STI). More preferably, both the first film and the second film directly contact the STI.

The angled ledge may also be located over a gate conductor and the first film and the second film may contact the gate conductor.

Preferably, the first film is a first silicon nitride film and the second film is a second nitride film. Also, preferably, the first film directly contacts spacers of the first MOSFET and the second film directly contacts spacers of the second MOSFET

Preferably, an etch stop layer is located directly atop the first film. Also, it is preferred that the etch stop layer is not present atop the second film. The etch stop layer is preferably a dielectric layer. The etch stop layer has an etch selectivity to the second film. In a highly preferred embodiment, the second film is a second silicon nitride film and the etch stop layer is a silicon oxide.

According to the present invention, a first method of fabricating a semiconductor structure is disclosed, which comprises:

providing a semiconductor substrate with a first MOSFET and a second MOSFET, wherein each of the first MOSFET and the second MOSFET has a gate conductor, spacers, and source and drain regions;

forming a first stressed film over the first MOSFET and over the second MOSFET;

removing a portion of the first stressed film over the second MOSFET;

forming a second stressed film over the first stressed film and the second MOSFET;

lithographically patterning the second stressed film such that an edge of a photoresist is within proximity of a step of the second stressed film over the first stressed film and is located toward the portion of the second stressed film that overlies the first stressed film from the step; and

etching the second stressed film such that an angled ledge that abuts the first stressed film is formed at an edge of the second stressed film and no portion of the second stressed film directly overlies the first stressed film.

Preferably, the first stressed film is formed over the entire semiconductor surface after the formation of the gate conductor and source and drain regions. After the formation of the first stressed film, the first stressed film overlies both the first MOSFET and the second MOSFET. The first stressed film is thereafter lithographically patterned and etched so that only the first transistor has an overlying first film while the second transistor does not have an overlying first film. The location of the step is defined as the location wherein a cross-sectional profile of the second stressed film has a substantially vertical outer surface. The outer surface does not contact the first stressed film.

According to the first embodiment of the present invention, the degree of proximity between the step and the edge of the photoresist is controlled such that the etching process can laterally etch the portion of the second stressed film that directly overlies the first stressed film with the lateral etching of the second stressed film. Preferably, the proximity is maintained by controlling the overlay of the photoresist to the step of the second stressed film over the first stressed film. The overlay of the photoresist with respect to the edge of the second stressed film is preferably less than twice the thickness of the second stressed film, and most preferably less than the thickness of the second stressed film to facilitate the sideward etching of the second stressed film during the etching process.

According to a second embodiment of the present invention, a method of fabricating a semiconductor structure is disclosed, which comprises:

providing a semiconductor substrate with a first MOSFET and a second MOSFET, wherein each of the first MOSFET and the second MOSFET has a gate conductor, spacers, and source and drain regions;

forming a first stressed film over the first MOSFET and over the second MOSFET;

removing a portion of the first stressed film over the second MOSFET;

forming a second stressed film over the first stressed film and the second MOSFET;

lithographically patterning the second stressed film such that an edge of a photoresist is within proximity of a step of the second stressed film over the first stressed film and is located toward the portion of the second stressed film that does not overlie the first stressed film from the step; and

etching the second stressed film such that an angled ledge that abuts the first stressed film is formed at an edge of the second stressed film and no portion of the second stressed film directly overlies the first stressed film.

The first stressed film and the second stressed film are formed in the same way as in the first embodiment described above. According to the second embodiment of the present invention, however, the edge of the photoresist is located on the opposite side of the step compared to the first embodiment, i.e., on the side without the first stressed film.

Preferably, the edge of the photoresist is a rounded edge formed with sublithographic assist features on a lithographic mask. The edge of the photoresist is scummed over a portion of the first stressed film to a step in the second stressed film. The degree of proximity between the step and the edge of the photoresist is controlled such that scumming of the photoresist, or accumulation of photoresist material that is dislodged from the sidewall of the photoresist at the foot of the photoresist edge to cover an adjacent area outside the original edge of the photoresist, completely covers the portion of the second stressed film between the original photoresist edge and the step. In other words, the accumulation of scummed material at the foot of the photoresist covers the portion of the second stressed film between the original photoresist edge and the step, thereby protecting the covered portion of the second stressed film.

Preferably, the proximity of the photoresist to the step of the second stressed film over the first stressed film is maintained by controlling the overlay. The overlay variation of the photoresist with respect to the step is preferably less than twice the thickness of the second stressed film, and most preferably less than the thickness of the second stressed film to facilitate the sideward etching of the second stressed film during the etching process.

In both the first and the second methods, preferably, the first stressed film applies a first stress at least to the channel of the first transistor, the second stressed film applies a second stress at least to the channel of the second transistor, and the first stress and the second stress are not equal. More preferably, the first stress and the second stress are opposite. For example, the first stress is a tensile stress and the second stress is a compressive stress. Alternatively, the first stress is a compressive stress and the second stress is a tensile stress. More preferably, both the first stress and the second stress are greater than about 150 MPa in magnitude. Most preferably, both the first stress and the second stress are greater than about 500 MPa in magnitude.

In both the first and the second methods, preferably, the first stressed film directly contacts the spacers of the first MOSFET and the source and drain regions of the first MOSFET and the second stressed film directly contacts the spacers of the second MOSFET and the source and drain regions of the second MOSFET. Also, preferably, an etch stop layer is formed above the first stressed film. For example, a blanket etch stop layer is deposited on the first stressed film and patterned with the first stressed film. Preferably, the etch stop layer provides selectivity to the etching process such that the etch removes the second stressed film selective to the etch stop layer. In an exemplary implementation, the etch stop layer is an oxide, the first stressed film is a first nitride, and the second stressed film is a second nitride, wherein the first nitride and the second nitride are not identical.

Both the first and the second methods according to the present invention produce the structure described above, wherein the first stressed film and the second stressed film abuts, that is, adjoins, each other only at their sides, i.e., at their “sidewalls.” The first stressed film and the second stressed film are not adjoined to each other at a top surface or at a bottom surface. The resulting structure applies a predetermined level of stress both to the first MOSFET and to the second MOSFET irrespective of the overlay of the photoresist that patterns the second stressed film. The self-aligned structure has a controlled level of stress to both types of MOSFETs irrespective of the overlay of the lithographic process that is used to align the second stressed film to the first stressed film.

### BRIEF DESCRIPTION OF THE DRAWINGS

FIG. 1 is a cross-section of a prior art structure with dual stressed films wherein a boundary region 72 contains a stack of both stressed films.

FIGS. 2-4 are sequential cross-sections of an exemplary structure for processes common to both a first embodiment and a second embodiment of the present invention.

FIGS. 5-7 are sequential cross-sections of the exemplary structure according to the first embodiment of the present invention.

FIGS. 8-10 are sequential cross-sections of the exemplary structure according to the second embodiment of the present invention.

FIG. 11 is a top down view of an exemplary structure according the present invention showing boundaries between two types of stressed films.

### DETAILED DESCRIPTION OF THE INVENTION

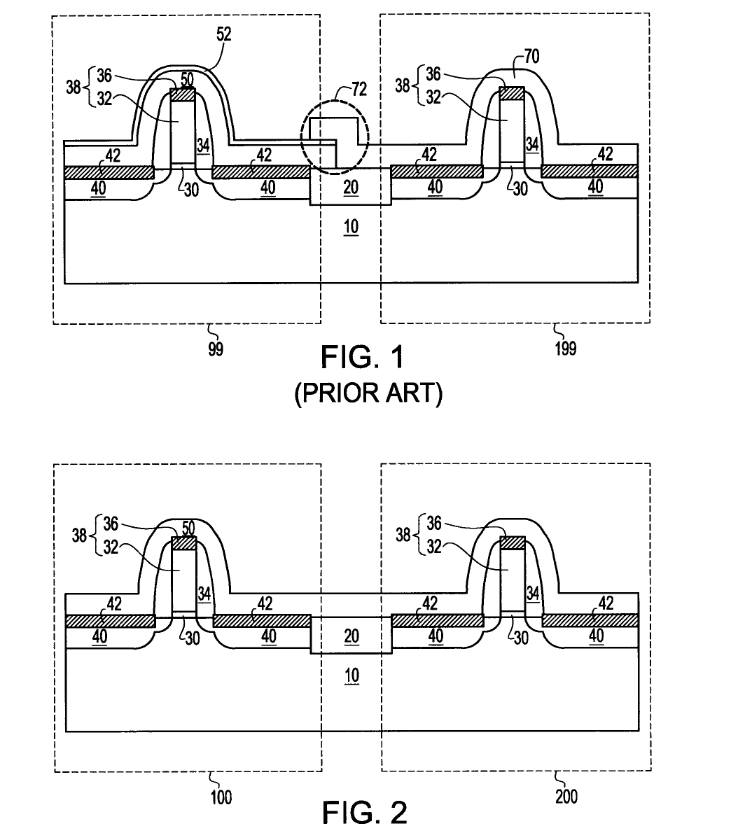

The present invention eliminates the stacked local structure 72 of the two stressed films (50, 70) according to the prior art as shown in FIG. 1. Instead, the present invention makes the two stressed films (50, 70) contact only at the sides without any vertical overlapping. As a result, full stress is applied to both types of devices even if they are located close to a boundary of the two stressed films (50, 70) according to the present invention.

According to the present invention, two embodiments of the methods for fabricating an inventive structure may be utilized. Since both embodiments use common processing methods and structures up to a certain point, both embodiments of the methods are described together herein until the two embodiments diverge from each other.

Referring to FIG. 2, a first MOSFET 100 and a second MOSFET 200 are shown with a substrate 10 and an STI 20. The substrate is preferably an epitaxial semiconductor substrate, i.e., a single crystalline semiconductor substrate. The semiconductor material may be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. The semiconductor substrate 10 may be a bulk substrate, a semiconductor-on-insulator (SOI) substrate, or a hybrid substrate. While the present invention is described with a bulk substrate, implementation of the present invention on an SOI substrate or on a hybrid substrate is explicitly contemplated herein.

The methods of forming MOSFET structures including wells (not shown in figures), threshold voltage adjustment implants and HALO implants (not shown in figures), STI 20, a gate dielectric 30 including high-K dielectric options, a gate conductor 38 which in this case comprises a gate polysilicon 32 and a gate silicide 36, a source and drain 40, and a source and drain silicide 42 are well known in the art. The first MOSFET 100 may be a PMOSFET and the second MOSFET 200 may be an NMOSFET. Alternatively, the first MOSFET 100 may be an NMOSFET and the second MOSFET 200 may be a PMOSFET.

According to the present invention, a first stressed film 50 is deposited both on the first MOSFET 100 and on the second MOSFET 200. The first stressed film 50 is preferably a dielectric film. The first stressed film 50 may be a silicon nitride, a silicon oxide, a silicon oxynitride, another dielectric material, or a stack of such materials. Most preferably, the first stressed film 50 is a silicon nitride film. The first stressed film 50 is formed over the entire top surface of the semiconductor substrate and covers both the first MOSFET 100 and the second MOSFET 200. Preferably, the first stressed film is deposited by chemical vapor deposition (CVD). Various methods of CVD are available such as low pressure chemical vapor deposition (LPCVD), plasma enhanced chemical vapor deposition (PECVD), sub-atmospheric chemical vapor deposition (SACVD) and high density plasma (HDP) deposition. Preferably, plasma enhanced chemical vapor deposition is used for deposition of the first stressed film 50.

The first stressed film 50 provides a first stress at least to the channel of the first MOSFET 100. If the first MOSFET 100 is an NMOMSFET, the first stressed film applies a tensile stress to the first MOSFET 100. The magnitude of the tensile stress is preferably greater than about 150 MPa and most preferably greater than about 500 MPa. If the first MOSFET 100 is a PMOSFET, the first stressed film applies a compressive stress to the first MOSFET 100. The magnitude of the compressive stress is preferably greater than about 150 MPa and most preferably greater than about 500 MPa. As deposited and prior to patterning of the first stressed film 50, the first stressed film applies the same level of stress to other devices below including the second MOSFET 200 in FIG. 2

The first stressed film 50 directly contacts the gate conductor 38 of the first MOSFET 100. As deposited and prior to patterning of the first stressed film 50, the first stressed film 50 also directly contacts the gate conductor 38 of the second MOSFET 200 as well.

The first stressed film 50 directly contacts the source and drain regions of the first MOSFET 100 which comprise the source and drain 40 and the source and drain silicide 42 of the first MOSFET 100. As deposited and prior to patterning of the first stressed film 50, the first stressed film 50 also directly contacts the source and drain regions of the second MOSFET 200 as well.

The first stressed film 50 directly contacts the spacer 34 of the first MOSFET 100. As deposited and prior to patterning of the first stressed film 50, the first stressed film 50 also directly contacts the spacer 34 of the second MOSFET 200 as well.

Preferably, the first stressed film 50 also directly contacts the STI 20.

The thickness of the first stressed film is preferably in the range from about 50 nm to about 100 nm.

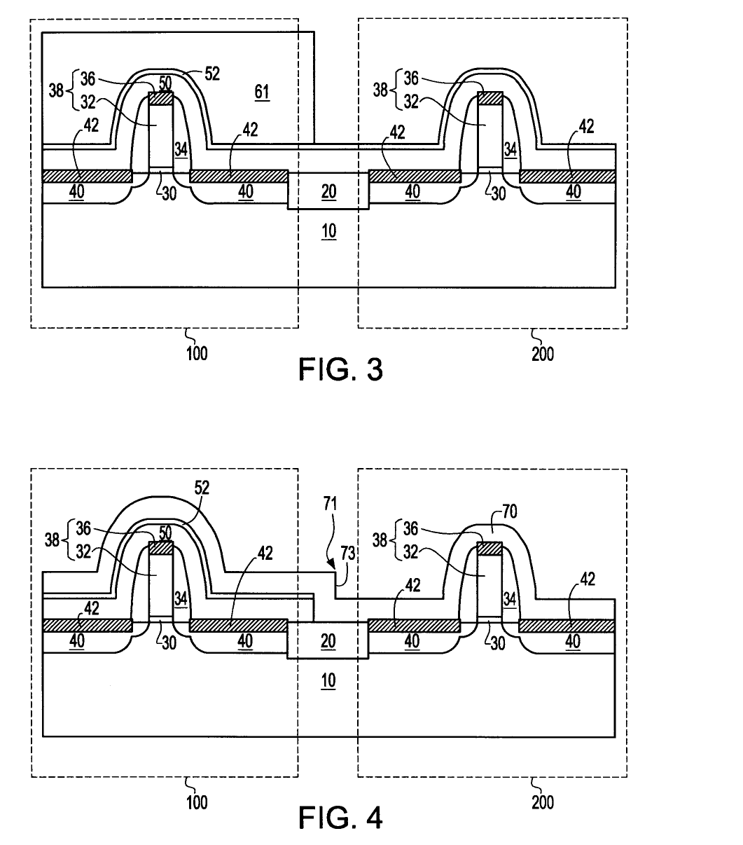

Preferably, an etch stop layer 52 is deposited over the first stressed film 50 as shown in FIG. 3. The etch stop layer 52 is a different material than a second stressed film 70 (to be shown in FIG. 4) to be subsequently deposited. Preferably, the etch stop layer 52 is a dielectric layer. The etch stop layer 52 is selected such that the etch process used for etching of the second stressed film 70 is selective to the etch stop layer 52 and does not substantially etch the etch stop layer 52. For example, if a second stressed film 70 is a silicon nitride film, a silicon oxide may be used as the etch stop layer 52. A thickness in the range from about 10 nm to about 20 nm is preferred for the etch stop layer 52. Any deposition method, including the various CVD methods mentioned above, may be utilized to deposit the etch stop layer 52.

A first photoresist 61 is applied over the top surface of the semiconductor substrate and lithographically patterned as shown in FIG. 3. Preferably, an etch stop layer 52 is employed as shown in FIG. 3 and the first photoresist 61 is applied over the etch stop layer 52. After patterning of the first photoresist 61, the area over the first MOSFET 100 is covered with the patterned photoresist 61 while the area over the second MOSFET 200 is exposed. The edge of the patterned photoresist 61 is preferably located over the STI 20.

The subsequent etch etches the exposed portion of the etch stop layer 52 and the underlying first stressed film 50. Preferably, the etch process for the first stressed film 50 is selective to the underlying material, i.e., the gate silicide 36 of the second MOSFET 200, the spacer 34 of the second MOSFET 200, the source and drain silicide 42 of the second MOSFET 200, and the STI 20.

Thereafter, a second stressed film 70 is deposited over the patterned first stressed film 50 as shown in FIG. 4. If an optional etch stop layer 52 is present in the structure, the second stressed film 70 is in direct contact with the etch stop layer 52, the sidewalls of the first stressed film 50, and the gate conductor 38 of the second MOSFET 200, the spacer 34 of the second MOSFET 200, and the source and drain silicide 42 of the second MOSFET 200. If an optional etch stop layer 52 is not present in the structure, the second stressed film 70 is in direct contact with the top surface of the first stressed film 50, the sidewalls of the first stressed film 50, and the gate conductor 38 of the second MOSFET 200, the spacer 34 of the second MOSFET 200, and the source and drain silicide 42 of the second MOSFET 200.

The second stressed film 70 is preferably a dielectric film. The second stressed film 70 may be a silicon nitride, a silicon oxide, a silicon oxynitride, another dielectric material, or a stack of such materials. Preferably, the second stressed film 70 is a silicon nitride. Preferably, the second stressed film is deposited by chemical vapor deposition (CVD) including any of the method mentioned for the deposition of the first stressed film 50.

A step 71 in the second stressed film 70 is formed along the edge of the underlying patterned first stressed film 50 and displaced from the underlying edge by about the thickness of the second stressed film 70 and toward the portion of the second stressed film 70 that does not overlie the patterned first stressed film 50. The location of the step 71 is defined as the location wherein a cross-sectional profile of the second stressed film 70 has a substantially vertical outer surface 73. The vertical outer surface 73 is a surface of the second stressed film 70, is substantially vertical, does not contact the first stressed film 50, and adjoins the substantially horizontal upper surfaces of the second stressed film 70 as shown in FIG. 4. The edge of the first stressed film 50 is preferably located over the STI 20. Furthermore, the step 71 of the second stressed film 70 is also preferably located over the STI 20. In this case, both the first stressed film 50 and the second stressed film 70 directly contact the STI 20.

The second stressed film 70 provides a second stress at least to the channel of the second MOSFET 200. If the first MOSFET 100 is an NMOSFET, the second MOSFET 200 is preferably a PMOSFET and the second stressed film applies a compressive stress to the second MOSFET 200. The magnitude of the compressive stress is preferably greater than about 150 MPa and most preferably greater than about 500 MPa. If the first MOSFET 100 is a PMOSFET, the second MOSFET 200 is preferably an NMOSFET and the second stressed film applies a tensile stress to the second MOSFET 200. The magnitude of the tensile stress is preferably greater than about 150 MPa and most preferably greater than about 500 MPa.

The second stressed film 70 directly contacts the gate conductor 38 of the second MOSFET 200 and the source and drain regions of the second MOSFET 200 which comprise the source and drain 40 and the source and drain silicide 42 of the second MOSFET 200. Also, the first stressed film 50 directly contacts the spacer 34 of the second MOSFET 200 and the STI 20.

The thickness of the first stressed film is preferably in the range from about 50 nm to about 100 nm.

A second photoresist 81 is applied over the entire top surface of the semiconductor structure shown in FIG. 4 and patterned to remove the portion of the second stressed film 70 from above the area of the first MOSFET 100. The edge of the patterned second photoresist 81 is placed within proximity of the step 71 of the second stressed film 70. The location of the edge of the second photoresist 81 relative to the step 71 depends on specific embodiments of the present invention.

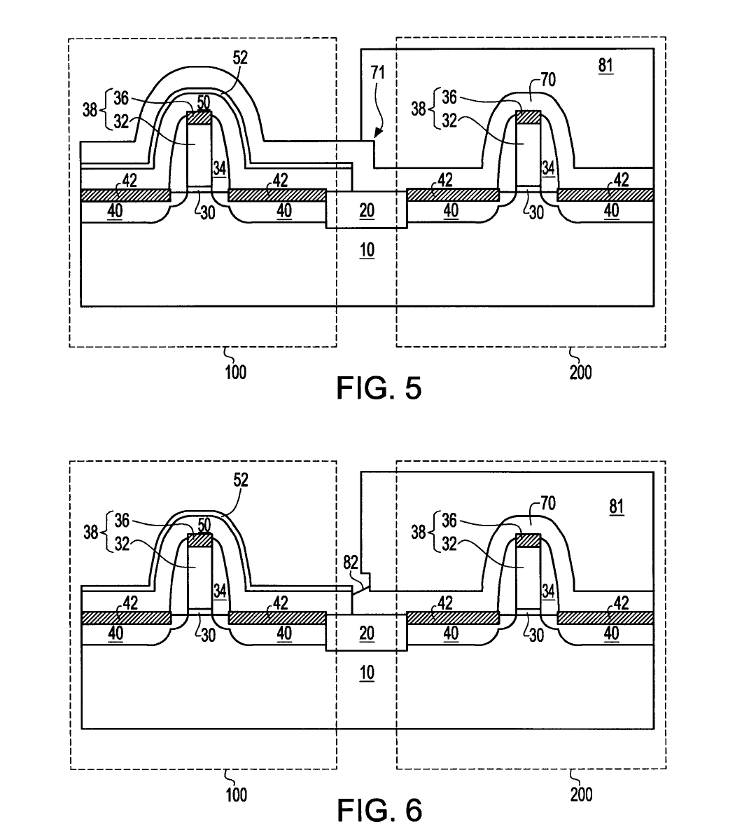

According to the first embodiment of the present invention, the edge of the second photoresist 81 is located on the step 71 or toward the portion of the second stressed film 70 that overlies the first stressed film 50, i.e., toward the first MOSFET 100 which is underneath a stack of the patterned first stressed film 50 and the blanket second stressed film 70 as shown in FIG. 5. In FIG. 5, the edge of the second photoresist 81 is to the left, or toward the first MOSFET 100, of the step 71. Preferably, the stack also contains an etch stop layer 52 between the first stressed film 50 and the second stressed film 70.

According to the first embodiment of the present invention, the degree of proximity between the step 71 and the edge of the second photoresist 81 is controlled such that a subsequent etching process laterally etches the portion of the second stressed film 70 that directly overlies the first stressed film 50. During the etch process, the portion of the second stressed film 70 close to the edge of the second photoresist 70 and covered by the second photoresist 70 is etched from the side. This results in an undercut of the second stressed film 70 from underneath the second photoresist 81. The resulting profile of the second stressed film 70 is shown in FIG. 6.

According to the first embodiment of the present invention, the etch leaves an angled ledge 82 near the contact of the second stressed film 70 with the first stressed film 50. This is because the etchants enter the undercut area of the second photoresist 81 from the side during the initial part of the etch process and etch the second stressed film horizontally but the direction of the etch changes vertically once the etchants pass the edge of the first stressed layer 50 during the latter part of the etch process. The width of the angled ledge 82 is substantially the same as the thickness of the second stressed film 70. The angle α of the angled ledge 82, as measured from a horizontal surface, is determined by the amount of overlay between the edge of the second photoresist 81 relative to the step 71. The angle α of the angled ledge 82 is also determined by the etch chemistry, especially the degree of anisotropy of the etch process used for etching the second stressed film 70. The angle α of the angled ledge 82 is between 0° and 60°, and preferably 0° and 45°, and most preferably 0° and 35°.

The proximity of the second photoresist 81 to the step 71 of the second stressed film 70 over the first stressed film 50 is preferably maintained by controlling the overlay. All of the second stressed film 70 is removed from the exposed area over which the second photoresist 81 is not present. The equivalent thickness for the etching of the second stressed film 70 is therefore greater than the thickness of the second stressed film 70. To insure sufficient process margin, a high selectivity of the etch process to the underlying etch stop layer 52 is preferred. The etch stop layer 52 is preferably a dielectric layer. For example, if the second stressed film 70 is a silicon nitride, the etch stop layer 52 may be a silicon oxide layer.

To insure that some of the second stressed film 70 still remains at the boundary of the first stressed film 50 and the second stressed film 70 after etching even in an extreme case of overlay variations in which the edge of the second photoresist coincides with the step 71, the equivalent thickness for the etch of the second stressed film 70 is less than the maximum thickness of the second stressed film 70 prior to etching, which is the sum of the thickness of the first stressed film 50, the thickness of the etch stop layer 52, and the thickness of the second stressed film 70. Since the thickness of the first stressed film 50 and the thickness of the second stressed film 70 tend to be similar and the thickness of the etch stop layer is often less than the thickness of the second stressed film 70, the overlay tolerance of the second photoresist 81 with respect to the step of the second stressed film is preferably less than about twice the thickness of the second stressed film 70, and most preferably less than about the thickness of the second stressed film 70 to facilitate the sideward etching of the second stressed film 70 during the etching process while insuring that all semiconductor surface is covered with a stressed film and no area is covered with both films or with no film.

In a demonstration of the present invention, a set of exemplary dimensions are provided. In this exemplary case, the first MOSFET 100 is an NMOSFET and the second MOSFET 200 is a PMOSFET. The first stressed film comprises a tensile nitride film. The thickness of the first stressed film 50 may be in the range from about 50 nm to about 100 nm. The etch stop layer is a silicon oxide layer. The thickness of the etch stop layer 52 may be in the range from about 10 nm to about 20 nm. The second stressed film 70 comprises a compressive nitride film. The thickness of the second stressed film may be in the range from about 50 to about 100 nm. An exemplary deep ultraviolet (DUV) lithography tool with an overlay tolerance of +/−35 nm (a total variation of 70 nm) is used for the alignment of the second photoresist 81. According to the requirements of the present invention, the equivalent thickness for the etching of the second stressed film 70 is preferably less than about twice the thickness of the second stressed film 70, which is in the range from about 100 nm to about 200 nm, and most preferably less than about 1.3× the thickness of the second stressed film 70, which is from about 50 nm to about 100 nm. In this exemplary case, the overlay tolerance (in total variation) is 70 nm, which is satisfied for a second stressed film 70 with a thickness greater than about 58 nm. The preferred thickness range changes with the performance of a lithography tool used to align the edge of the second photoresist 81 to the step 71. The example above does not place limiting constraints on the dimensions of structures of the present invention but should be construed only as an exemplary implementation of the present invention demonstrating its practicability.

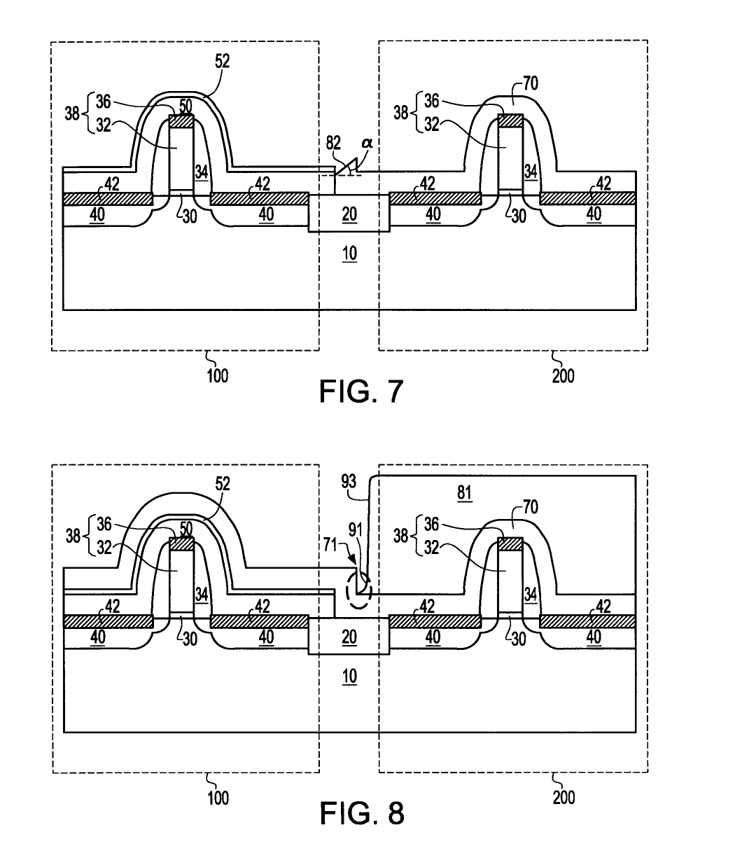

After removing the photoresist 81, the resulting structure, as shown in FIG. 7, has a first MOSFET 100, a second MOSFET 200, a first stressed film 50 over the first MOSFET 100, and a second stressed film 70 over the second MOSFET 200. The first stressed film 50 applies a first stress to the first MOSFET 100 and the second stressed film 70 applies a second stress to the second MOSFET 200. Preferably, the two stresses are not equal. More preferably, the two stresses are opposite in polarity. If the first MOSFET 100 is an NMOSFET and the second MOSFET 200 is a PMOSFET, the first stressed film 50 preferably applies a tensile stress to the channel of the NMOSFET and the second stressed film 70 preferably applies a compressive stress to the channel of the PMOSFET. If the first MOSFET 100 is a PMOSFET and the second MOSFET 200 is an NMOSFET, the first stressed film 50 preferably applies a compressive stress to the channel of the NMOSFET and the second stressed film 70 preferably applies a tensile stress to the channel of the PMOSFET.

An aspect of the present invention is that the edge of the second stressed film 70 is self aligned to the edge of the first stressed film 50 as shown in FIG. 7. The first film 50 abuts, or adjoins the second film 70. The first stressed film 50 does not overlie the second stressed film 70. The second stressed film 70 does not overlie the first stressed film 50.

According to the second embodiment of the present invention, the edge of the second photoresist 81 is located on the step 71 or toward the portion of the second stressed film 70 that does not overlie the first stressed film 50, i.e., toward the second MOSFET 200 which is underneath the second stressed film 70 as shown in FIG. 8. In this embodiment, the edge of the second photoresist 81 is to the right, or toward the second MOSFET 200, of the step 71.

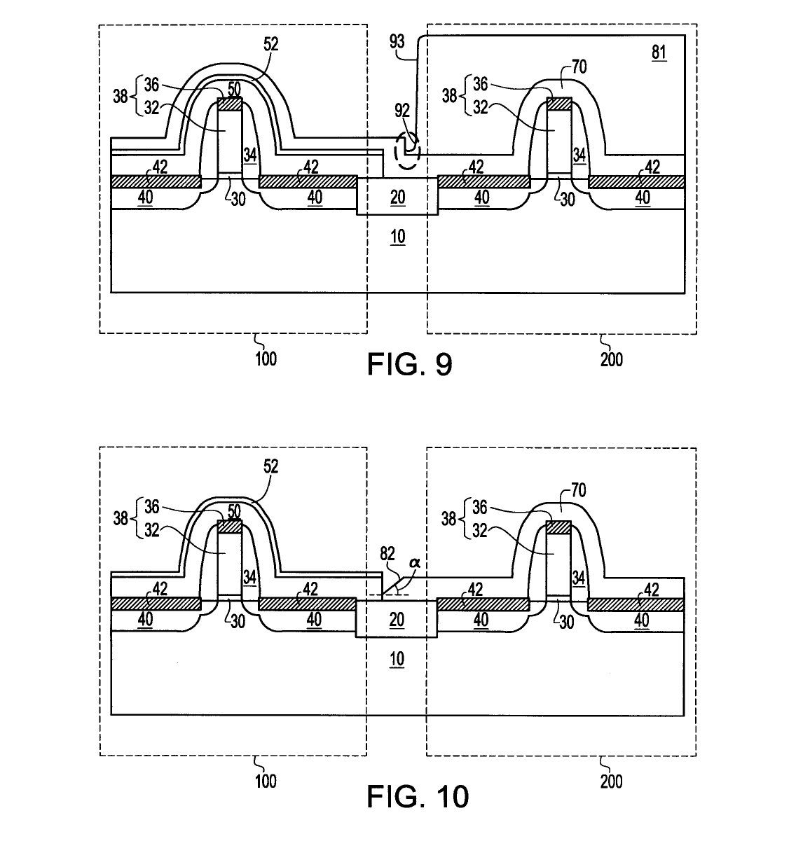

According to the second embodiment of the present invention, the degree of proximity between the step 71 and the edge of the second photoresist 81 is controlled such that the scumming of the second photoresist 81 forms a scummed portion 92 that completely covers the portion of the second stressed film 70 between the original edge of the second photoresist as shown in FIG. 8 and the step 71. Scumming of the second photoresist 81 is an accumulation of the material from the second photoresist 81 that is dislodged from the sidewall of the second photoresist 81 at the foot 91 of the original edge 93 of the second photoresist 81 as shown in FIG. 8 to cover an adjacent area outside the original edge of the second photoresist 81. The scummed portion 92 of the photoresist 81 thus protects the covered portion of the second stressed film 70 between the original edge of the second photoresist 81 and the step 71. The structure during the etching of the second stressed film 70, in which the second stressed film 70 is partly etched and a scummed portion 92 develops out of the original foot 91 of the photoresist 81 between the original edge of the second photoresist 81 and the step 71, is shown in FIG. 9.

Lithographic techniques are employed to form a “rounded edge” 93 of the photoresist 81 near the step 71 as shown in FIG. 8, in which the edge 93 of the photoresist 81 near the step 71 has a slope that deviates from a vertical angle and a rounded top and a foot 91 at the bottom. If two edges of the photoresist 81 are located within a sublithographic distance or near a critical dimension of a lithographic tool employed, such rounded edges are naturally formed by interference of the photons by the pattern on the mask during the exposure. For example, the intensity of the light impinging on an edge of the pattern on the photoresist changes only gradually, causing the resist to develop a rounded edge 93. If another edge of the photoresist 82 is not located, sublithographic assist features are placed on the mask near the location corresponding to the edge 93 on the photoresist 81 such that the resulting interference causes the intensity of the light vary gradually near the edge of the resist. By employing such lithographic techniques, a rounded edge 93 and a foot 91 are formed at each boundary between the PFET area and the NFET area, i.e., near the step 71 in FIG. 8.

Therefore, the structure according to the second embodiment of the present invention has an angled ledge 82 near the contact of the second stressed film 70 with the first stressed film 50 in a similar fashion as in the first embodiment. Unlike the first embodiment of the present invention, this angled ledge is caused by the viscosity of the scummed second photoresist 81. The scumming occurs during the etch process of the second stressed film. The second photoresist 81 is scummed when the material on or near the original sidewall, or edge, of the second photoresist 81 is dislodged by the etchants during the etch of the second stressed film and flows down the sidewall of the second photoresist 81 due to gravity. Due to its high viscosity, however, the dislodged material does not freely fall down like a solid or flow like a liquid with low viscosity. Instead, the dislodged material slowly slides down the sidewall of the second photoresist, which is not the same as the original photoresist sidewall before the etch, and accumulates at the foot of the original edge of the second photoresist. As the etch process continues and more material is dislodged and flows down the changing sidewall of the second photoresist 81, more material accumulates at the foot of the second photoresist 81 to form scummed photoresist. Furthermore, with the accumulation of more material, the scummed photoresist grows bigger and also flows away from the original edge of the second photoresist 81.

Thus, the etch of the second stressed film leaves an angled ledge 82 near the contact of the second stressed film 70 with the first stressed film 50 as the scummed photoresist gradually flows and protects area away from the location where the step 71 existed prior to the etch. The width of the angled ledge 82 is substantially the same as the thickness of the second stressed film 70. The angle α of the angled ledge 82, as measured from a horizontal surface, is determined by the amount of overlay between the edge of the second photoresist 81 relative to the step 71. Also, the angle α of the angled ledge 82 is determined by the etch chemistry and the chemical properties of the second photoresist 82, especially, the viscosity of the second photoresist 81. The angle α of the angled ledge 82 is between 0° and 60°, and preferably 0 and 45°, and most preferably 0 and 35°.

The etch process and requirements are similar to those in the first embodiment. The proximity of the second photoresist 81 to the step 71 of the second stressed film 70 over the first stressed film 50 is preferably maintained by controlling the overlay. All of the second stressed film 70 is removed from the exposed area over which the second photoresist 81 is not present. The equivalent thickness for the etch of the second stressed film 70 is therefore greater than the thickness of the second stressed film 70. To insure sufficient process margin, a high selectivity of the etch process to the underlying etch stop layer 52 is desired. The etch stop layer 52 is preferably a dielectric layer. If the second stressed film 70 is a silicon nitride, the etch stop layer 52 may be a silicon oxide layer.

To insure that some of the second stressed film 70 still remains after etching in an extreme case of overlay variations in which the edge of the second photoresist coincides with the step 71, the equivalent thickness for the etch of the second stressed film 70 is less than the maximum thickness of the second stressed film 70, which is the sum of the thickness of the first stressed film 50, the thickness of the etch stop layer 52, and the thickness of the second stressed film 70. Since the thickness of the first stressed film 50 and the thickness of the second stressed film 70 tend to be similar and the thickness of the etch stop layer is often less than the thickness of the second stressed film 70, the overlay tolerance of the second photoresist 81 with respect to the step of the second stressed film is preferably less than about twice the thickness of the second stressed film 81, and most preferably less than about the thickness of the second stressed film 81 to facilitate the sideward etching of the second stressed film 70 during the etching process.

The resultant structure of the second embodiment of the present invention as shown in FIG. 10 share all the characteristics of the corresponding structure according to the first embodiment of the present invention. In fact, both structures share the same structural characteristics.

A “hybrid” implementation of the first and the second embodiments, wherein both the sideward etching according to the first embodiment and the scumming of the second photoresist 81 according the second embodiment, may be employed to achieve an increased overlay tolerance on the alignment of the edge of the second photoresist 81 to the step 71 of the second stressed film 70 over the first stressed film 50. Such hybrid implementation of the two embodiments of the present invention is herein explicitly contemplated.

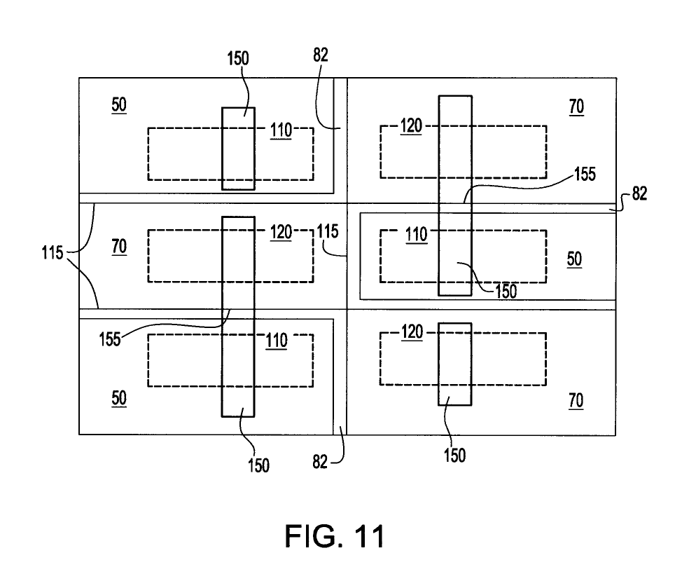

Referring to FIG. 11, a top-down view of an exemplary structure with boundaries (115, 155) between the first stressed film 50 and the second stressed film 70 according to the present invention is shown. Locations of first type MOSFETs 110, which are underneath the first stressed film 50, and locations of second type MOSFETs 120, which are underneath the second stressed film 70, are shown in dotted lines. The gate conductors 150 are shown in solid lines. The boundary (115, 155) between the first stressed film 50 and the second stressed film 70 comprises the boundary 115 over STI between the first stressed film 50 and the second stressed film 70 and the boundary 155 over gate conductors 150 between the first stressed film 50 and the second stressed film 70. The non-overlapping characteristic of the first stressed film 50 and the second stressed film 70 in the structure is evident in FIG. 11.

An angled ledge 82 is formed at every boundary between the first stressed film 50 and the second stressed film 70. The angled ledge 82 is formed within the second stressed film 70. All angled ledges 82 has a width that is substantially the same as the thickness of the second stressed film 70. Also, all angled ledges contact the first stressed film 70. No portion of the first stressed film 50 is located over the second stressed film 70. Similarly, no portion of the second stressed film 70 is located over the first stressed film 50. The first stressed film 50 abuts, or “adjoins,” the second stressed film 70, or more precisely, the angled ledges 82 of the second stressed film 70, only through their sidewalls according to the present invention.

The present invention can also be practiced without stress in the first stressed film 50 or without stress in the second stressed film 70 while maintaining the same structure. Such implementation is explicitly contemplated herein.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A semiconductor structure comprising:
a substrate:
a first metal-on-semiconductor field effect transistor (MOSFET) with a first channel formed on said substrate;
a second MOSFET with a second channel formed on said substrate;
a first film located over said first MOSFET and providing a first stress at least to the channel of said first transistor; and
a second film located over said second MOSFET and providing a second stress at least to the channel of said second transistor, wherein said second film has an angled ledge that is self-aligned to an edge of said first film and said first stress is not equal to said second stress.

2. The semiconductor structure of claim 1, wherein said first film abuts said second film, said first film does not overlie said second film, and said second film does not overlie said first film.

3. The semiconductor structure of claim 2, wherein both said first film and said second film are dielectric films.

4. The semiconductor structure of claim 3, wherein said first stress is a tensile stress to and said second stress is a compressive stress.

5. The semiconductor structure of claim 4, wherein said first film has a tensile stress greater than about 150 MPa and said second film has a compressive stress greater than about 150 MPa.

6. The semiconductor structure of claim 4, wherein said first MOSFET is an n-type MOSFET (NMOSFET) and said second MOSFET is a p-type MOSFET (PMOSFET).

7. The semiconductor structure of claim 4, wherein said first film directly contacts a gate conductor of said first MOSFET and source and drain regions of said first MOSFET.

8. The semiconductor structure of claim 4, further comprising a shallow trench isolation (STI), wherein said first film abut said second film over said STI and said first film and said second film contact said STI.

9. The semiconductor structure of claim 4, wherein said angled ledge is located over a gate conductor and said first film and said second film contact said gate conductor.

10. The semiconductor structure of claim 4, wherein said first film is a first silicon nitride film and said second film is a second silicon nitride film.

11. The semiconductor structure of claim 4, wherein said first film directly contacts spacers of said first MOSFET and said second film directly contacts spacers of said second MOSFET.

12. The semiconductor structure of claim 4, further comprising an etch stop layer directly atop said first film.

13. A method of fabricating a semiconductor structure, comprising:
providing a semiconductor substrate with a first MOSFET and a second MOSFET;
forming a first stressed film over said first MOSFET and over said second MOSFET;
removing a portion of said first stressed film over said second MOSFET;
forming a second stressed film over said first stressed film and said second MOSFET;
lithographically patterning said second stressed film such that an edge of a photoresist is within proximity of a step of said second stressed film over said first stressed film and is located toward the portion of said second stressed film that overlies said first film from said step; and
etching said second stressed film such that an angled ledge that abuts said first stressed film is formed at an edge of said second stressed film and no portion of said second stressed film directly overlies said first stressed film.

14. The method of claim 13, wherein a portion of said second stressed film is etched from under said photoresist during said etching of said second stressed film.

15. The method of claim 14, wherein the overlay tolerance of said photoresist with respect to a step in said second stressed film is less than about twice the thickness of said second stressed film.

16. The method of claim 15, wherein said first stressed film has a first stress and said second layer has a second stress, wherein said first stress and said second stress are not equal.

17. The method of claim 16, wherein said first stressed film directly contacts spacers of said first MOSFET and source and drain regions of said first MOSFET and said second stressed film directly contacts spacers of said second MOSFET and source and drain regions of said second MOSFET.

18. The method of claim 16, further comprising forming an etch stop layer over said first stressed film.

19. The method of claim 18, wherein said etch stop layer is an oxide, said first stressed film is a first nitride, and said second stressed film is a second nitride, wherein said first nitride and said second nitride are not identical.

20. A method of fabricating a semiconductor structure, comprising:
providing a semiconductor substrate with a first MOSFET and a second MOSFET;
forming a first stressed film over said first MOSFET and over said second MOSFET;
removing a portion of said first stressed film over said second MOSFET;
forming a second stressed film over said first stressed film and said second MOSFET;
lithographically patterning said second stressed film such that an edge of a photoresist is within proximity of a step of said second stressed film over said first stressed film and is located toward the portion of said second stressed film that does not overlie said first film from said step; and
etching said second stressed film such that an angled ledge that abuts said first stressed film is formed at an edge of said second stressed film and no portion of said second stressed film directly overlies said first stressed film.

21. The method of claim 20, wherein said edge of said photoresist is a rounded edge formed with sublithographic assist features on a lithographic mask.

22. The method of claim 21, wherein said edge of said photoresist is scummed over a portion of said first stressed film and extends to a step in said second stressed film.

23. The method of claim 22, wherein the overlay of said photoresist with respect to said step in said second stressed film is less than twice the thickness of said second stressed film.

24. The method of claim 23, wherein said first stressed film has a first stress and said second layer has a second stress, wherein said first stress and said second stress are not equal.

25. The method of claim 24, wherein said first stressed film directly contacts spacers of said first MOSFET and source and drain regions of said first MOSFET and said second stressed film directly contacts spacers of said second MOSFET and source and drain regions of said second MOSFET.

26. The method of claim 24, further comprising forming an etch stop layer over said first stressed film.

27. The method of claim 26, wherein said etch stop layer is an oxide, said first stressed film is a first nitride, and said second stressed film is a second nitride, wherein said first nitride and said second nitride are not identical.

28. A method of fabricating a semiconductor structure, comprising:
providing a semiconductor substrate with a first MOSFET and a second MOSFET;
forming a first stressed film over said first MOSFET and over said second MOSFET;
removing a portion of said first stressed film over said second MOSFET;
forming a second stressed film over said first stressed film and said second MOSFET;
lithographically patterning said second stressed such that an edge of a photoresist is within proximity of a step of said second stressed film over said first stressed film; and
etching said second stressed film such that an angled ledge that abuts said first stressed film is formed at an edge of said second stressed film and no portion of said second stressed film directly overlies said first stressed film.

29. The method of claim 28, wherein said second stressed film is etched from under said photoresist during said etching of said second stressed film and said edge of said photoresist is a rounded edge formed with sublithographic assist features on a lithographic mask.

30. The method of claim 29, wherein said first stressed film has a first stress and said second layer has a second stress, wherein said first stress and said second stress are not equal.
